(19) United States
(12) Patent Application Publication
(10) Pub. No.: US 2007/0220385 A1
(43) Pub. Date: Sep. 20, 2007

(54) Semiconductor device provided with function for screening test regarding operating speed

(75) Inventor: Toshio Ogawa, Kawasaki (JP)

Correspondence Address: ARENT FOX PLLC, 1050 CONNECTICUT AVENUE, N.W., SUITE 400, WASHINGTON, DC, 20036, US

(73) Assignee: FUJITSU LIMITED

(21) Appl. No.: 11/487,340

(22) Filed: Jul. 17, 2006

(30) Foreign Application Priority Data
Mar. 17, 2006 (JP) 2006-075004

(51) Int. Cl. G01R 31/28

(52) U.S. Cl. 714/726

(57) ABSTRACT

A semiconductor device includes one or more margin detecting circuits, each of which includes a first flip-flop having a first clock signal input node coupled to a clock supply node and a first data input node coupled to a data supply node, a second flip-flop having a second clock signal input node coupled to the clock supply node and a second data input node coupled to the data supply node, a delay element situated between the clock supply node and the second clock input node or between the data supply node and the second data input node, and a check circuit configured to check whether data stored in the first flip-flop matches data stored in the second flip-flop.

### CROSS-REFERENCE TO RELATED APPLICATIONS

The present application is based upon and claims the benefit of priority from the prior Japanese Patent Application No. 2006-075004 filed on Mar. 17, 2006, with the Japanese Patent Office, the entire contents of which are incorporated herein by reference.

### BACKGROUND OF THE INVENTION

1. Field of the Invention

The present invention generally relates to semiconductor devices and tests for semiconductor devices, and particularly relates to a semiconductor device equipped with a test function and a test method using such a semiconductor device.

2. Description of the Related Art

Semiconductor devices such as RAM (Random Access Memory), CPU (Central Processing Unit), and FPGA (Field Programmable Gate Array) are subjected to a screening test regarding operation speed prior to shipment from the factory. In such a screening test regarding operation speed, an LSI tester is used to monitor the output data while changing the operation speed (i.e., clock frequency) of the semiconductor device to be tested, thereby determining the upper speed limit at which the semiconductor device can properly operate. Those semiconductor devices which are confirmed by the screening test to be capable of properly operating at high speed are sold at premium price, and the semiconductor devices that can properly operate only at low speed are sold at low price.

In order to perform the screening test regarding operation speed as described above, test data prepared in advance are input into the semiconductor device, and the output data produced by the semiconductor device in response to the input data are compared with an expected data value, thereby checking whether the semiconductor device is properly operating. Such check needs to be performed with respect to various input data sets as well as with respect to various operating speeds (clock frequency). Because of such labor, a substantial amount of time and costs is required to perform a screening test regarding operating speed with high precision.

[Patent Document 1] Japanese Patent Application Publication No. 2000-266819

[Patent Document 2] Japanese Patent Application Publication No. 2002-16226

[Patent Document 3] Japanese Patent Application Publication No. 2004-144599

[Patent Document 4] Japanese Patent Application Publication No. 61-149871

Accordingly, there is a need for a semiconductor device that allows a highly-accurate screening test regarding operating speed to be performed with a small amount of time and labor, and, also, there is a need for a test method using such a semiconductor device.

### SUMMARY OF THE INVENTION

It is a general object of the present invention to provide a semiconductor device and test method that substantially obviate one or more problems caused by the limitations and disadvantages of the related art.

Features and advantages of the present invention will be presented in the description which follows, and in part will become apparent from the description and the accompanying drawings, or may be learned by practice of the invention according to the teachings provided in the description. Objects as well as other features and advantages of the present invention will be realized and attained by a semiconductor device and test method particularly pointed out in the specification in such full, clear, concise, and exact terms as to enable a person having ordinary skill in the art to practice the invention.

To achieve these and other advantages in accordance with the purpose of the invention, the invention provides a semiconductor device, comprising one or more margin detecting circuits, each of which includes a first flip-flop having a first clock signal input node coupled to a clock supply node and a first data input node coupled to a data supply node, a second flip-flop having a second clock signal input node coupled to the clock supply node and a second data input node coupled to the data supply node, a delay element situated between the clock supply node and the second clock input node or between the data supply node and the second data input node, and a check circuit configured to check whether data stored in the first flip-flop matches data stored in the second flip-flop.

A method of testing a semiconductor device includes causing the semiconductor device to operate at operating frequency, the semiconductor device including a first flip-flop having a first clock signal input node coupled to a clock supply node and a first data input node coupled to a data supply node, a second flip-flop having a second clock signal input node coupled to the clock supply node and a second data input node coupled to the data supply node, a delay element situated between the clock supply node and the second clock input node or between the data supply node and the second data input node, and a check circuit configured to check whether data stored in the first flip-flop matches data stored in the second flip-flop, increasing the operating frequency in a stepwise manner, and monitoring an output of the check circuit.

According to at least one embodiment of the present invention, the margin detecting circuit is provided for the first flip-flop in the semiconductor device, so that the margin detecting circuit displaces the timing of one of a data signal and a synchronizing clock signal, and causes the second flip-flop to load the data signal in response to the synchronizing clock signal whose relative timing is displaced, followed by checking whether data loading is properly performed. With this provision, a check can be made as to whether a sufficient margin exists for the first flip-flop in the semiconductor device. The operating frequency is increased in a stepwise manner while monitoring whether a sufficient margin exists. The operating frequency observed at the time it is determined that there is no sufficient margin serves as an indication of the operating frequency at which the semiconductor device can properly operate at maximum speed. This provision makes it possible to perform a highly-accurate screening test regarding operating speed with a small amount of time and labor.

### BRIEF DESCRIPTION OF THE DRAWINGS

Other objects and further features of the present invention will be apparent from the following detailed description when read in conjunction with the accompanying drawings, in which:

FIG. 1 is a drawing showing an example of the configuration of a margin detecting circuit attached to a flip-flop in a semiconductor device;

FIG. 2 is a drawing showing an example of the configuration of the semiconductor device according to the present invention;

FIG. 3 is a drawing showing another example of the configuration of the semiconductor device according to the present invention; and

FIG. 4 is a drawing showing another example of the configuration of a margin detecting circuit attached to a flip-flop in a semiconductor device.

### DESCRIPTION OF THE PREFERRED EMBODIMENTS

In the following, embodiments of the present invention will be described with reference to the accompanying drawings.

The present invention provides a margin detecting circuit, which will later be described, to all or some of flip-flops provided in the semiconductor device. When the margin detecting circuits are to be provided to only some of the flip-flops in the semiconductor device, these flip-flops may be those situated along critical paths on which the conditions for proper operation are tight with respect to timing. Namely, if there are 10,000 paths including flip-flops, for example, a predetermined number of paths on which timing is believed to be most tight among the 10,000 paths may be selected, and the margin detecting circuits may be attached to those selected paths.

A single margin detecting circuit is provided in one-to-one correspondence to each flip-flop (hereinafter referred to as a first flip-flop), and includes a flip-flop (hereinafter referred to as a second flip-flop) disposed in parallel to the first flip-flop. The first flip-flop receives a data signal and a synchronizing clock signal, and loads (latches) the received data signal in response to the received synchronizing clock signal. The margin detecting circuit slightly displaces the timing of one of the data signal and synchronizing clock signal supplied to the first flip-flop, thereby generating a data signal and synchronizing clock signal whose relative timing is displaced. The second flip-flop receives the data signal and synchronizing clock signal whose relative timing is displaced, and loads (latches) the received data signal in response to the received synchronizing clock signal.

If there is a sufficient margin (i.e., setup margin or hold margin) for the first flip-flop, the second flip-flop can also properly load the data. In this case, the data stored in the first flip-flop and the data stored in the second flip-flop are the same. In the case where there is not a sufficient margin (i.e., setup margin or hold margin) for the first flip-flop, as in the case where the semiconductor device is made to operate with high-speed clock signal, the second flip-flop cannot properly load correct data, resulting in the data stored in the first flip-flop being different from the data stored in the second flip-flop. If the data stored in the first flip-flop and the data stored in the second flip-flop do not match as in this case, it can be concluded that the margin of the first flip-flop is not sufficient.

In this manner, the present invention attaches a margin detecting circuit to a flip-flop in the semiconductor device, so that the margin detecting circuit displaces the timing of one of a data signal and a synchronizing clock signal, and causes another flip-flop to load the data signal in response to the synchronizing clock signal whose relative timing is displaced, followed by checking whether data loading is properly performed. With this provision, a check can be made as to whether a sufficient margin exists for the flip-flop in the semiconductor device. The operating frequency is gradually increased (in a stepwise manner) while monitoring whether a sufficient margin exists. The operating frequency observed at the time it is determined that there is no sufficient margin serves as an indication of the operating frequency at which the semiconductor device can properly operate at maximum speed.

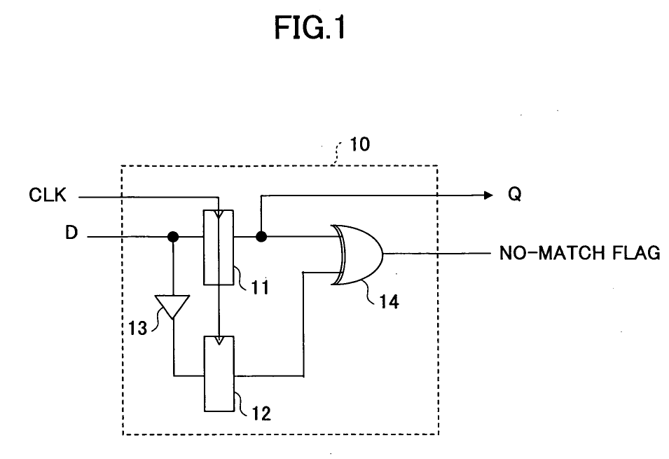

FIG. 1 is a drawing showing an example of the configuration of a margin detecting circuit attached to a flip-flop in a semiconductor device. In FIG. 1, the setup-margin detecting circuit 10 includes a flip-flop 11, a flip-flop 12, a delay element 13, and an XOR gate 14. The flip-flop 11 is a flip-flop that is a circuit element serving to achieve the intended operation of the semiconductor device. In a semiconductor device such as a RAM or CPU, a large number of flip-flops are used as circuit elements for achieving the intended operation (function) of the RAM or CPU. On of such flip-flops is the flip-flop 11.

In the semiconductor device according to the present invention, the setup-margin detecting circuit 10 as shown in FIG. 1 is attached to all or some of the flip-flops provided in the semiconductor device. Namely, all or some of the flip-flops of the manufactured semiconductor device is formed as the setup-margin detecting circuit 10 in which the flip-flop 12, the delay element 13, and the XOR gate 14 are disposed around the flip-flop of interest.

As previously described, when the margin detecting circuits are to be provided to only some of the flip-flops in the semiconductor device, these flip-flops may be those situated along critical paths on which the conditions for proper operation are tight with respect to timing. Namely, if there are 10,000 paths including flip-flops, for example, a predetermined number of paths on which timing is believed to be most tight among the 10,000 paths may be selected, and the setup-margin detecting circuits may be attached to those selected paths.

The flip-flop 11 receives input data D from a circuit element situated at the preceding stage, and loads (latches) the input data D in synchronization with a clock signal CLK, thereby supplying the latched data as an Q output to a circuit element situated at the following stage. This data path is a data propagation path directly connected to the intended operation of the semiconductor device.

The flip-flop 12 provided in parallel to the flip-flop 11 receives the same clock signal CLK that is supplied to the flip-flop 11. The flip-flop 12 further receives, as its data input, the delayed data that is made by delaying the input data D through the delay element 13 by a predetermined delay time. The flip-flop 12 loads (latches) the delayed data in synchronization with the clock signal CLK.

In this manner, the setup-margin detecting circuit 10 of FIG. 1 slightly displaces the timing of the data signal D, which is one of the data signal D and the synchronizing clock signal CLK supplied to the flip-flop 11, thereby generating a data signal and synchronizing clock signal whose relative timing is displaced. The flip-flop 12 receives the data signal and synchronizing clock signal CLK whose relative timing is displaced, and loads (latches) the received data signal in response to the received synchronizing clock signal CLK.

The XOR gate 14 functions as a match/no-match check circuit, and performs an exclusive-OR operation between the output data of the flip-flop 11 and the output data of the flip-flop 12. If the output data (stored data) of the flip-flop 11 is the same as the output data (stored data) of the flip-flop 12, the output of the XOR gate 14 becomes LOW. If the output data (stored data) of the flip-flop 11 is different from the output data (stored data) of the flip-flop 12, the output of the XOR gate 14 becomes HIGH.

The output of the XOR gate 14 serves as a no-match flag that is output from the setup-margin detecting circuit 10. If the no-match flag is HIGH, this indicates that there is no sufficient setup margin for the flip-flop 11 of the setup-margin detecting circuit 10.

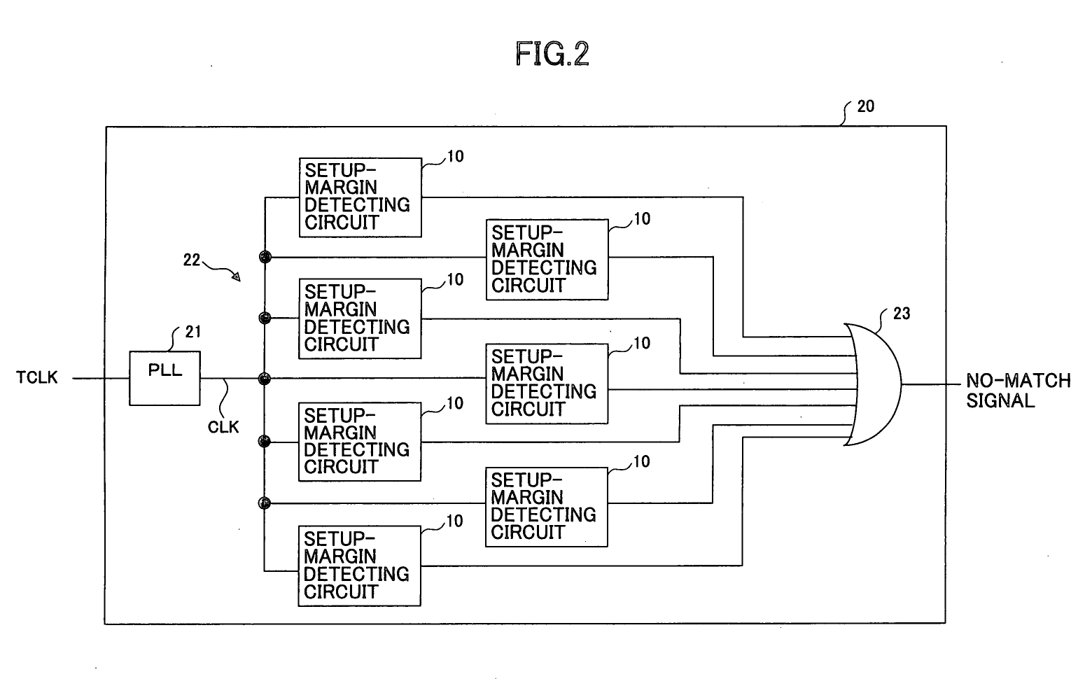

FIG. 2 is a drawing showing an example of the configuration of the semiconductor device according to the present invention. A semiconductor device 20 of FIG. 2 includes a plurality of setup-margin detecting circuits 10, a PLL circuit 21, a clock tree 22, and an OR gate 23. Each of the setup-margin detecting circuits 10 is the setup-margin detecting circuit 10 having the configuration shown in FIG. 1 attached to all or some of the flip-flops provided in the semiconductor device 20. Each setup-margin detecting circuit 10 receives the clock signal CLK from the PLL circuit 21, and supplies a no-match flag as its output to the OR gate 23. For the sake of convenience of illustration, FIG. 2 does not show data paths for the input data D and the output data Q shown in FIG. 1.

The PLL circuit 21 generates the clock signal CLK in response to an external clock signal supplied from an exterior. The clock signal CLK is supplied to each part of the semiconductor device 20 via the clock tree 22. Based on the clock signal CLK supplied in this manner, the various internal circuits of the semiconductor device 20 operate. At the time of a screening test regarding operating speed, the above-noted external clock signal is a clock signal TCLK supplied from an LSI tester. The LSI tester gradually increases the frequency of the clock signal TCLK from a low frequency to a high frequency.

As the frequency of the clock signal CLK increases in response to the increase in the frequency of the clock signal TCLK of the LSI tester, the no-match flag output from one of the setup-margin detecting circuits 10 becomes HIGH at a certain frequency. The output of the OR gate 23 becomes HIGH when at least one of the no-match flags output from the setup-margin detecting circuits 10 changes to HIGH.

The output of the OR gate 23 is supplied to the exterior of the semiconductor device 20 as a no-match signal. Detecting this no-match signal, the external LSI tester learns the occurrence of the situation in which no sufficient setup margin exists for one of the flip-flops in the semiconductor device at the operating frequency (i.e., the frequency of the clock signal CLK) corresponding to the clock signal TCLK used at that instant. Namely, the operating frequency used at that instance serves as an indication of the operating frequency at which the semiconductor device can properly operate.

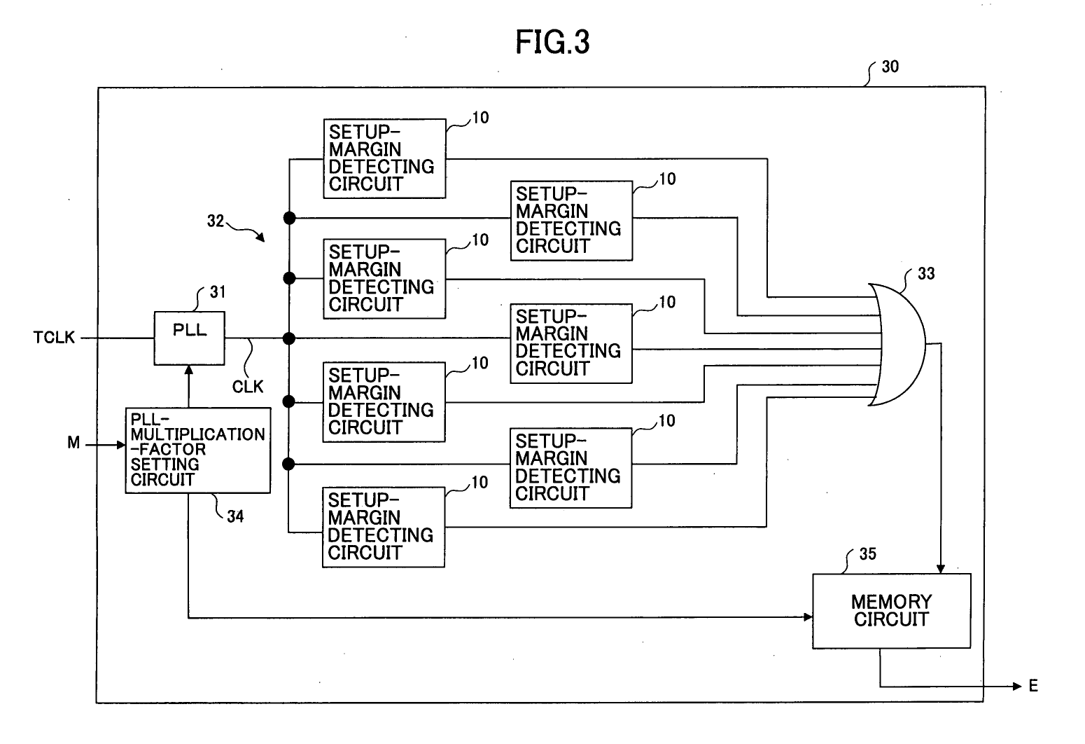

FIG. 3 is a drawing showing an example of the configuration of the semiconductor device according to the present invention. A semiconductor device 30 of FIG. 3 includes a plurality of setup-margin detecting circuits 10, a PLL circuit 31, a clock tree 32, an OR gate 33, a PLL-multiplication-factor setting circuit 34, and a memory circuit 35. Each of the setup-margin detecting circuits 10 is the setup-margin detecting circuit 10 having the configuration shown in FIG. 1 attached to all or some of the flip-flops provided in the semiconductor device 30. Each setup-margin detecting circuit 10 receives the clock signal CLK from the PLL circuit 31, and supplies a no-match flag as its output to the OR gate 33. For the sake of convenience of illustration, FIG. 3 does not show data paths for the input data D and the output data Q shown in FIG. 1.

The PLL circuit 31 generates the clock signal CLK in response to an external clock signal supplied from an exterior. The clock signal CLK is supplied to each part of the semiconductor device 30 via the clock tree 32. Based on the clock signal CLK supplied in this manner, the various internal circuits of the semiconductor device 30 operate. At the time of a screening test regarding operating speed, the above-noted external clock signal is a clock signal TCLK supplied from an LSI tester.

In the semiconductor device 30 shown in FIG. 3, the PLL circuit 31 generates the clock signal CLK by multiplying the frequency of the clock signal CLK. Typically, the PLL circuit 31 includes a phase comparator to compare the phases of a first input clock signal and second input clock signal, a low-pass filter to integrate the voltage signal responsive to the phase difference output from the phase comparator, a voltage-controlled oscillator to oscillate at frequency responsive to the output voltage of the low-pass filter, and a frequency divider to divide the frequency of the oscillating signal output from the voltage-controlled oscillator so as to generate the above-noted second input clock signal. The above-noted first input clock signal is the input clock signal TCLK into the PLL circuit 31, and the oscillating signal of the voltage-controlled oscillator is the output clock signal CLK output from the PLL circuit 31.

The multiplication factor of the PLL circuit 31 (i.e., the frequency-division factor of the above-noted frequency divider) is set by the PLL-multiplication-factor setting circuit 34. The PLL-multiplication-factor setting circuit 34 receives a control signal M specifying the multiplication factor from the external LSI tester, and sets the PLL circuit 31 to the multiplication factor indicated by the control signal M. The PLL-multiplication-factor setting circuit 34 supplies data indicative of the multiplication factor set in the PLL circuit 31 to the memory circuit 35.

The LSI tester gradually increases the multiplication factor specified by the control signal M. As the frequency of the clock signal CLK increases in response to the increase in the multiplication factor, the no-match flag output from one of the setup-margin detecting circuits 10 becomes HIGH at a certain frequency. The output of the OR gate 23 becomes HIGH when at least one of the no-match flags output from the setup-margin detecting circuits 10 changes to HIGH.

The output of the OR gate 23 is supplied to the memory circuit 35. The memory circuit 35 is triggered by the output of the OR gate 23 to store the data indicative of the multiplication factor supplied from the PLL-multiplication-factor setting circuit 34. Specifically, as the output of the OR gate 23 becomes HIGH, the memory circuit 35 responds by latching the data indicative of the multiplication factor. The memory circuit 35 may be configured such that, once data is stored, the stored data is retained until a reset signal is supplied from the exterior, for example.

The contents of the memory circuit 35 are readable from the exterior in response to an instruction from the external LSI tester. For example, the memory circuit 35 may be incorporated into a scan chain that is read at the time of test operation, such that the data of the memory circuit 35 is successively propagated through the scan flip-flops constituting the scan chain to be supplied to the exterior from an end terminal E of the scan chain.

The data of the memory circuit 35 read in this manner corresponds to the data indicative of the multiplication factor of the PLL circuit 31, the multiplication factor being used at the instance such situation as no sufficient setup margin exists for one of the flip-flops in the semiconductor device occurs for the first time when the operating frequency is gradually increased. Accordingly, it is possible to know, based on this data, the operating frequency serving as an indication of the operating frequency at which the semiconductor device can properly operate.

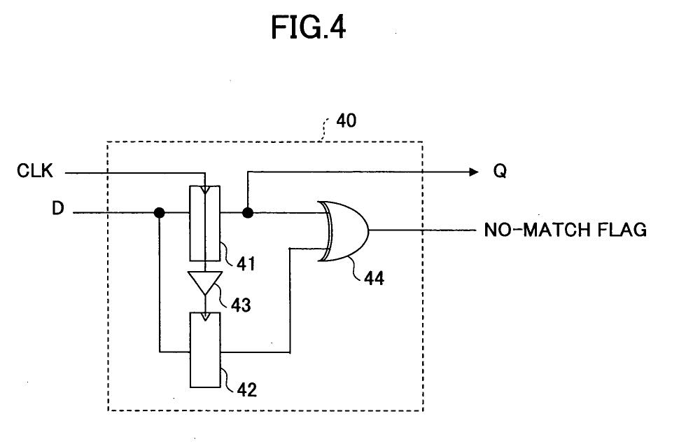

FIG. 4 is a drawing showing another example of the configuration of a margin detecting circuit attached to a flip-flop in a semiconductor device. In FIG. 4, a hold-margin detecting circuit 40 includes a flip-flop 41, a flip-flop 42, a delay element 43, and an XOR gate 44. The flip-flop 41 is a flip-flop that is a circuit element serving to achieve the intended operation of the semiconductor device. In a semiconductor device such as a RAM or CPU, a large number of flip-flops are used as circuit elements for achieving the intended operation (function) of the RAM or CPU. On of such flip-flops is the flip-flop 41.

In the semiconductor device according to the present invention, the hold-margin detecting circuit 40 as shown in FIG. 4 is attached to all or some of the flip-flops provided in the semiconductor device. Namely, all or some of the flip-flops of the manufactured semiconductor device is formed as the hold-margin detecting circuit 40 in which the flip-flop 42, the delay element 43, and the XOR gate 44 are disposed around the flip-flop of interest.

As previously described, when the margin detecting circuits are to be provided to only some of the flip-flops in the semiconductor device, these flip-flops may be those situated along critical paths on which the conditions for proper operation are tight with respect to timing. Namely, if there are 10,000 paths including flip-flops, for example, a predetermined number of paths on which timing is believed to be most tight among the 10,000 paths may be selected, and the hold-margin detecting circuits may be attached to those selected paths.

The flip-flop 41 receives input data D from a circuit element situated at the preceding stage, and loads (latches) the input data D in synchronization with a clock signal CLK, thereby supplying the latched data as an Q output to a circuit element situated at the following stage. This data path is a data propagation path directly connected to the intended operation of the semiconductor device.

The flip-flop 42 provided in parallel to the flip-flop 41 receives the same input data D that is supplied to the flip-flop 41. The flip-flop 42 further receives, as its clock input, the delayed clock signal that is made by delaying the clock signal CLK through the delay element 43 by a predetermined delay time. The flip-flop 42 loads (latches) the input data D in synchronization with the delayed clock signal.

In this manner, the hold-margin detecting circuit 40 of FIG. 4 slightly displaces the timing of the clock signal CLK, which is one of the data signal D and the synchronizing clock signal CLK supplied to the flip-flop 41, thereby generating a data signal and synchronizing clock signal whose relative timing is displaced. The flip-flop 42 receives the data signal D and synchronizing clock signal whose relative timing is displaced, and loads (latches) the received data signal D in response to the received synchronizing clock signal.

The XOR gate 44 functions as a match/no-match check circuit, and performs an exclusive-OR operation between the output data of the flip-flop 41 and the output data of the flip-flop 42. If the output data (stored data) of the flip-flop 41 is the same as the output data (stored data) of the flip-flop 42, the output of the XOR gate 44 becomes LOW. If the output data (stored data) of the flip-flop 41 is different from the output data (stored data) of the flip-flop 42, the output of the XOR gate 44 becomes HIGH.

The output of the XOR gate 44 serves as a no-match flag that is output from the hold-margin detecting circuit 40. If the no-match flag is HIGH, this indicates that there is no sufficient hold margin for the flip-flop 41 of the hold-margin detecting circuit 40.

The hold-margin detecting circuit 40 of FIG. 4 may be used in place of the setup-margin detecting circuits 10 shown in FIG. 2. In the semiconductor device having such a configuration, the output of the OR gate performing an OR operation between all the no-match flags is supplied to the exterior of the semiconductor device as a no-match signal. Detecting this no-match signal, the external LSI tester learns the occurrence of the situation in which no sufficient hold margin exists for one of the flip-flops in the semiconductor device at the operating frequency (i.e., the frequency of the clock signal CLK) corresponding to the clock signal TCLK used at that instant. Namely, the operating frequency used at that instance serves as an indication of the operating frequency at which the semiconductor device can properly operate.

Further, the hold-margin detecting circuit 40 of FIG. 4 may be used in place of the setup-margin detecting circuits 10 shown in FIG. 3. In the semiconductor device having such a configuration, the data of the memory circuit supplied to the exterior of the device corresponds to the data indicative of the multiplication factor of the PLL circuit, this multiplication factor being used at the instance such situation as no sufficient hold margin exists for one of the flip-flops in the semiconductor device occurs for the first time when the operating frequency is gradually increased. Accordingly, it is possible to know, based on this data, the operating frequency serving as an indication of the operating frequency at which the semiconductor device can properly operate.

In the setup-margin detecting circuit 10 of FIG. 1 or the hold-margin detecting circuit 40 of FIG. 4, the delay element may be a variable delay circuit. Such variable delay circuit may be configured such that a plurality of delay elements are connected in series to delay the input signal successively, and a selector is provided to receive a plurality of delayed signals having different delays output from the respective delay circuits, one of the delayed signals being selected by the selector so as to output a signal having a desired delay. With this provision, the use of the variable delay circuit as the delay element makes it possible to set the delay time freely, thereby providing a more diligent screening test regarding operating speed.

Further, the present invention is not limited to these embodiments, but various variations and modifications may be made without departing from the scope of the present invention.

What is claimed is:

1. A semiconductor device, comprising one or more margin detecting circuits, each of which includes:
a first flip-flop having a first clock signal input node coupled to a clock supply node and a first data input node coupled to a data supply node;
a second flip-flop having a second clock signal input node coupled to the clock supply node and a second data input node coupled to the data supply node;
a delay element situated between the clock supply node and the second clock input node or between the data supply node and the second data input node; and
a check circuit configured to check whether data stored in the first flip-flop matches data stored in the second flip-flop.

2. The semiconductor device as claimed in claim 1, further comprising a logic circuit configured to consolidate outputs of the one or more margin detecting circuits, each of the outputs being output from the check circuit.

3. The semiconductor device as claimed in claim 2, wherein an output of the logic circuit is supplied to an exterior of the semiconductor device.

4. The semiconductor device as claimed in claim 2, further comprising:
a PLL circuit configured to generate a clock signal to be supplied to the clock supply node; and
a memory circuit configured to store data indicative of a multiplication factor of the PLL circuit in response to an output from the logic circuit.

5. The semiconductor device as claimed in claim 4, further comprising a scan chain configured to supply the data stored in the memory circuit to an exterior of the semiconductor device.

6. The semiconductor device as claimed in claim 1, wherein the delay element is a variable delay circuit operable to change a delay time.

7. A method of testing a semiconductor device, comprising:
causing the semiconductor device to operate at operating frequency, the semiconductor device including a first flip-flop having a first clock signal input node coupled to a clock supply node and a first data input node coupled to a data supply node, a second flip-flop having a second clock signal input node coupled to the clock supply node and a second data input node coupled to the data supply node, a delay element situated between the clock supply node and the second clock input node or between the data supply node and the second data input node, and a check circuit configured to check whether data stored in the first flip-flop matches data stored in the second flip-flop;
increasing the operating frequency in a stepwise manner; and
monitoring an output of the check circuit.
